(19) United States
(12) Patent Application Publication
(10) Pub. No.: US 2009/0045986 A1
(43) Pub. Date: Feb. 19, 2009

(54) ILLUMINATED KEYBOARD AND LIGHT GUIDE FOR GRAPHIC SYMBOLS AND METHOD

(75) Inventors: Gustav FABRENIUS, Dalby (SE); William TOLBERT, Malmo (SE); Goran Walter SCHACK, Ahus (SE); Carl Magnus WALDT, Kavlinge (SE); Damir KAJIC, Lund (SE); Anna Beatrice RAVIK, Helsingborg (SE); Par Magnus Christian RAGNARSSON, Lund (SE); Henrik Edvadr Gustav SVEDBERG, Malmo (SE); Janne Antero RANTALA, Oulu (FI); Jyrki Antero KIVINIEMI, Oulu (FI)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/923,999

(22) Filed: Oct. 25, 2007

Related U.S. Application Data
(60) Provisional application No. 60/955,868, filed on Aug. 14, 2007.

(51) Int. Cl. H03K 17/94

(52) U.S. Cl. 341/22

(57) ABSTRACT

A keyboard includes a housing, a plurality of keys, a flexible support adapted to support a plurality of keys with respect to the housing, at least part of the flexible support being at least partly transmissive of light to conduct light to illuminate a plurality of keys, a light block adapted to tend to block light transmission between a pair of relatively adjacent parts of the flexible support, and a source of input light adapted to provide light to such respective relatively adjacent parts of the flexible support. A method of illuminating keys of a keyboard having a plurality of keys includes selectively illuminating sequentially one or more, but less than all, of the keys of the keyboard.

### CROSS-REFERENCE TO RELATED APPLICATION

This application claims the benefit of U.S. Provisional Patent Application Ser. No. 60/955,868, filed Aug. 14, 2007, the entire disclosure of which is hereby incorporated by reference.

### TECHNICAL FIELD

The present invention relates generally, as indicated, to illuminated keyboard and light guide for graphic symbols and method and, more particularly, to such a keyboard and light guide used in a portable communication device.

### BACKGROUND

Various techniques have been used to illuminate a keyboard, such as, for example, a keyboard for a computer or the like, or a keyboard used as a keypad for a portable communication device. In some instances the entire keyboard is illuminated using one or several common light sources. In some instances a dedicated light source is provided to each key or to respective specific keys of a keyboard.

### SUMMARY

According to one aspect of the invention, the keys of a portable communication device that are arranged in rows and columns are illuminated one row at a time or one column at a time.

According to another aspect, such keys are illuminated in a random or repeating sequence.

According to another aspect, two light sources illuminate three keys in a row of a keypad of a portable communication device.

According to another aspect, a flexible, e.g., elastomeric, mat supports keys for a keyboard, and light is directed into the mat at selected locations to provide for illumination of respective keys.

According to another aspect, a method of operating a keyboard includes selectively illuminating respective keys less than all the keys.

According to another aspect, a key has plural icons to designate different respective functions, and the icons can be selectively individually illuminated to indicate that operation of the given key has a function then indicated by the icon.

Another aspect of the invention relates to a keyboard, including a plurality of keys, a flexible support adapted to support a plurality of keys, at least part of the flexible support being at least partly transmissive of light to conduct light to illuminate a plurality of keys, and a light block adapted to tend to block light transmission between a pair of relatively adjacent parts of the flexible support.

Another aspect relates to the flexible support comprising a silicon mat.

Another aspect relates to the light block comprising a groove in the flexible support between respective parts thereof, and light blocking material in the groove.

Another aspect relates to the light blocking material comprising material molded directly in the groove.

Another aspect relates to the keyboard and further including a plurality of light sources, and recesses in a surface of the flexible material, the recesses adapted to conduct light from respective light sources directly to respective at least partly light transmissive parts of the flexible support.

Another aspect relates to the keyboard and further including a reflective coating on at least part of the flexible support to avoid light leakage and to provide a light guide effect.

Another aspect relates to the keys being attached to the flexible support.

Another aspect relates to the keyboard further including a respective icon on a plurality of the keys.

Another aspect relates to the keys being arranged in a plurality of rows with one or more keys in each row, a plurality of light sources arranged with respect to the flexible support and the light block thereof such that the keys of different rows are illuminated by a different respective a light source.

Another aspect relates to the keyboard and further including a control adapted to control operation of the respective light sources to illuminate less than all rows of keys at a time.

Another aspect relates to the control being adapted to control operation of the respective light sources to illuminate each of the rows of keys in a repeating sequence or random sequence.

Another aspect relates to at least a plurality of the keys being selectively operable to effect an input to a portable communication device.

Another aspect relates to the keyboard and further including a housing, a circuit board of portable electronic equipment including a support and circuitry in the housing, the flexible support mounted in the housing with respect to the housing or the circuit board, a plurality of the keys being manually selectively operable to effect providing an input to the circuitry, and a source of input light adapted to provide light to respective parts of the flexible support to illuminate one or more respective keys.

Another aspect relates to the keyboard and further comprising a source of illumination adapted to illuminate a plurality of the keys, and a control adapted to control operation of the source of illumination to provide for random or sequential illuminating of respective keys or groups of keys.

Another aspect relates to the control being adapted to detect a prescribed input and in response to such prescribed input controlling operation of the source of illumination in a prescribed manner.

Another aspect relates to the control being adapted to detect an incoming telephone call as such prescribed input.

According to another aspect of the invention, a portable electronic equipment includes a keyboard having a number of keys adapted to provide inputs to the portable electronic equipment, a keyboard illumination system, including a flexible support adapted to support keys of the keyboard, the flexible support being at least partly light transmissive to conduct light to illuminate a plurality of keys, and a light block in the flexible support adapted to block transmission of light in the flexible support from illuminating at least one other key.

Another aspect relates to wherein the flexible support comprises a number of relatively thick rib portions providing stiffness for the flexible support, and relatively thin flexible portions between respective ribs.

Another aspect relates to the portable electronic equipment further including raised surfaces on the relatively thin flexible portions with an open clearance circumscribed by the raised surfaces providing space for at least a portion of a light source to align with the open clearance to provide light input for transmission in the flexible support, and further comprising light emitting diodes aligned with respective open clearances adapted to provide light into the flexible support.

Another aspect relates to wherein the flexible support includes locations at one surface for a number of keys positionable in respective parallel rows and/or respective parallel columns, the light block comprises a light block between respective parallel rows or parallel columns, and inputs to the flexible support such that light input to the flexible support at a light input in one row or column is provided to illuminate adjacent keys in such one row or column.

Another aspect relates to wherein the keys are in respective rows and a number of the rows include locations for at least three keys, the light input for a row comprises at least two light inputs, each located between a pair of locations for keys of that row, and the light block blocks at least a substantial amount of light transmission between respective rows.

Another aspect relates to inclusion of operating circuitry adapted to operate and to carry out functions of the portable electronic equipment.

Another aspect relates to the portable electronic equipment being a portable communication device, and wherein the operating circuitry comprises a communication module to send and receive at least one of voice or text, and further comprising a housing for the keyboard, keyboard illumination system and operating circuitry.

Another aspect of the invention relates to a method of illuminating keys of a keyboard having a plurality of keys arranged in at least one of a plurality of rows or a plurality of columns, including selectively illuminating sequentially one or more, but less than all, of the keys of the keyboard in a random or a repetitive sequence.

Another aspect relates to the method wherein the selectively illuminating comprising illuminating at least a row of keys or a column of keys without illuminating another row of keys or column of keys.

According to another aspect of the invention, a key for a keyboard, includes a key body, the key body having an at least partly light transmissive portion, a separator in the key body adapted to block light transmission between at least two parts of the key body, and at least two light inlets, one adapted to provide light to one part of the key body and one to provide light to another part of the key body.

Another aspect of the invention relates to a touch pad keyboard comprising a molded part that is integral including light transmissive or transparent sections and a grid of opaque sections between such transparent sections.

Another aspect relates to a keyboard, including a housing, a plurality of keys, a flexible support adapted to support a plurality of keys with respect to the housing, at least part of the flexible support being at least partly transmissive of light to conduct light to illuminate a plurality of keys, a light block adapted to tend to block light transmission between a pair of relatively adjacent parts of the flexible support, and a source of input light adapted to provide light to such respective relatively adjacent parts of the flexible support.

One or more other aspects relate to such keyboard, wherein the keys comprising a keypad of a portable communication device; the flexible support comprising a silicon mat; further comprising a groove in the flexible support between respective parts thereof, and light blocking material in the groove; the light blocking material comprising material molded directly in the groove; the light blocking material comprising at least one of non-transparent ink or non-transparent paint; further comprising recesses in a surface of the flexible material, the recesses adapted to conduct light directly to a respective least partly transmissive part of the flexible support; the source of input light comprising light emitting diodes; further comprising a reflective coating on at least part of the flexible support to avoid light leakage and to provide a light guide effect; the keys being attached to the flexible support; further comprising a respective icon on a plurality of the keys; wherein the keys are arranged in four rows of three keys, the source of input light comprises a plurality of light sources such the keys of different rows are illuminated by a different respective a light source; wherein the a plurality of light sources illuminate a plurality of the keys in each row of keys; further comprising a control adapted to operate the respective light sources to illuminate less than all rows of keys at a time; the control being adapted to operate the respective light sources to illuminate each of the rows of keys in a repeating sequence; the control being adapted to operate the respective light sources to illuminate each of the rows of keys in a random sequence; at least a plurality of the keys being selectively operable to effect an input to a portable communication device; and/or further comprising a circuit board including a support and circuitry in the housing, and a plurality of the keys being manually selectively operable to effect providing an input to the circuitry.

Another aspect relates to an illuminated keyboard, including a plurality of keys, a source of illumination adapted to illuminate a plurality of the keys, and a control adapted to control operation of the source of illumination to provide for sequential illuminating of respective keys or groups of keys.

One or more other aspects relate to the keyboard, wherein the control is adapted to control operation of the source of illumination to provide for sequential illumination of respective keys or groups of keys in a random sequence; wherein the control is adapted to control operation of the source of illumination to provide for sequential illumination of respective keys or groups of keys in a repeating sequence; the keys being arranged in a plurality of rows and columns, and the control being adapted to control operation of the source of illumination for illuminating less than all the rows or columns of keys at one time; further comprising a separator adapted to block light transmission between respective rows or respective columns of keys; the control being adapted to control operation of the source of illumination for illuminating only one row or one column of keys at one time; a portable communication device including a keyboard with one or more of the above features, and wherein a plurality of the keys comprise a keypad of the portable communication device and are manually operable to provide an input to the portable communication device; the control being adapted to detect a prescribed input and in response to such prescribed input controlling operation of the source of illumination in a prescribed manner; the control being adapted to detect an incoming telephone call as such prescribed input.

Another aspect relates to a keyboard illumination system, including a flexible support adapted to support keys of the keyboard, the flexible support being at least partly light transmissive to conduct light to illuminate a plurality of keys, and a light block in the flexible support adapted to block transmission of light in the flexible support from illuminating at least one other key.

One or more other aspects relate to the keyboard illumination system wherein the flexible support comprises a number of relatively thick rib portions providing stiffness for the flexible support, and relatively thin flexible portions between respective ribs; further comprising raised surfaces on the relatively thin flexible portions with an open clearance circumscribed by the raised surfaces providing space for at least a portion of a light source to align with the open clearance to provide light input for transmission in the flexible support; further comprising light emitting diodes aligned with respective open clearances adapted to provide light into the flexible support; the flexible support includes locations at one surface for a number of keys positionable in respective parallel rows, the light block comprises a light block between respective parallel rows, and inputs to the flexible support such that light input to the flexible support at a light input in one row is provided to illuminate adjacent keys in such one row; wherein each row includes locations for three keys, the light input for a row comprises two light inputs, each located between a pair of locations for keys of that row; further comprising activators on a surface of the flexible support in alignment with respective locations for respective keys to operate circuitry of a portable communication device in response to actuation of a respective key; the flexible support comprising silicon rubber; the flexible support comprising a groove in a surface of the flexible support in overlying alignment with a rib, and the light block comprising light blocking material in the groove; and/or the light blocking material comprising at least one of paint, ink or molded material in the groove.

Another aspect relates to a support for keys of a keyboard, including a flexible material adapted to support a plurality of keys, at least part of the flexible material being at least partly light transmissive to conduct light and adapted to provide such light to keys, an input adapted to receive input light to a plurality of the at least partly light transmissive parts, and a light non-transmissive portion in the flexible material adapted to tend to block transmission of light between adjacent parts of the flexible support.

One or more other aspects relate to a support for keys of a keyboard, wherein the flexible material comprises a number of relatively thick rib portions providing stiffness for the flexible material, and relatively thin flexible portions between respective ribs; further comprising raised surfaces on the relatively thin flexible portions with an open clearance circumscribed by the raised surfaces providing space for at least a portion of a light source to align with the open clearance to provide light input for transmission in the flexible material; further comprising light emitting diodes aligned with respective open clearances adapted to provide light into the flexible material; the flexible support includes locations at one surface for a number of keys positionable in respective parallel rows, the light non-transmissive material comprises a light block between respective parallel rows, and inputs to the flexible material such that light input to the flexible material at a light input in one row is provided to illuminate adjacent keys in such one row; wherein each row includes locations for three keys, the light input for a row comprises two light inputs, each located between a pair of locations for keys of that row; further comprising activators on a surface of the flexible material in alignment with respective locations for respective keys to operate circuitry of a portable communication device in response to actuation of a respective key; the flexible material comprising silicon rubber; and/or the flexible material comprising a groove in a surface of the flexible material in overlying alignment with a rib, and the light block comprising light blocking material in the groove; the light blocking material comprising at least one of paint, ink or molded material in the groove.

Another aspect relates to a key for a keyboard, including a key body, the key body having an at least partly light transmissive portion, a separator in the key body adapted to block light transmission between at least two parts of the key body, and at least two light inlets, one adapted to provide light to one part of the key body and one to provide light to another part of the key body.

One or more other aspects relate to a key for a keyboard, the key body comprising polycarbonate; the key body being optically transparent; the key body having a light blocking coating on at least a part of the outside thereof; the coating comprising a metalized coating; the coating comprising a reflective coating to reflect light from the key body back into the key body; the separator comprising light non-transmissive material in the key body; the separator being molded into the key body; further comprising an icons or indicia at the respective parts of the key body; further comprising light emitting diodes selectively operable to direct light to respective light inlets; further comprising a control operable to determine which of the light inlets receives a light input to provide illumination for part of the key while the separator blocks illumination that is in the one part from illuminating the other part of the key; and/or the separator comprising polycarbonate acrylonitrile butadiene styrene (PC/ABS).

Another aspect of the invention relates to a method of illuminating keys of a keyboard having a plurality of keys, including selectively illuminating sequentially one or more, but less than all, of the keys of the keyboard.

One or more other aspects of the method relate to the selectively illuminating comprising illuminating in a sequentially repetitive manner; the selectively illuminating comprising illuminating in a random manner; the selectively illuminating comprising illuminating row by row of keys; the selectively illuminating comprising illuminating a row of keys without illuminating another row of keys; the selectively illuminating comprising illuminating column by column of keys; and/or the selectively illuminating comprising illuminating a column of keys without illuminating another column of keys.

Another aspect of the invention relates to a touch pad keyboard including a molded part that is integral including light transmissive or transparent sections and a grid of opaque sections between such transparent sections.

One or more other aspects relate to a touch pad keyboard, the sections and grid being molded as an integral structure; further comprising a printed circuit board aligned with the molded part to be activated by inputs to the molded part; further comprising a flexible circuit board having circuits thereon, the molded part being aligned with the flexible circuit board to be pressed to complete circuits on the circuit board; further comprising light inputs to respective sections of the molded part.

These and further aspects and features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended thereto.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

Many aspects of the invention can be better understood with reference to the following drawings. The components in the drawings are not necessarily to scale, emphasis instead being placed upon clearly illustrating the principles of the present invention. To facilitate illustrating and describing some parts of the invention, corresponding portions of the drawings may be exaggerated in size, e.g., made larger in relation to other parts than in an exemplary device actually made according to the invention. Elements and features depicted in one drawing or embodiment of the invention may be combined with elements and features depicted in one or more additional drawings or embodiments. Moreover, in the drawings, like reference numerals designate corresponding parts throughout the several views and figures.

### BRIEF DESCRIPTION OF THE DRAWINGS

In the annexed drawings:

FIG. 1 is a schematic illustration of a portable communication device, e.g., in the form of a portable telephone;

FIG. 2 is a schematic block system diagram of circuitry of the portable telephone for carrying out operation thereof in a manner described below;

FIG. 3 is a schematic end elevation view, partly in section of the portable telephone looking generally in the direction of arrows 3-3 of FIG. 1;

FIG. 4 is a schematic side elevation view, partly in section, of the portable telephone looking generally in the direction of the arrows 4-4 of FIG. 1;

FIG. 5 is a top plan view of a flexible support for keys of the keyboard of the portable telephone of FIG. 1 illustrating the keys in four rows of three keys each as an example of a conventional telephone keypad, there being light non-transmissive dividers between respective rows of the support;

FIG. 6 is a “see through” top plan view of the flexible support looking through the resilient flexible support of FIG. 5;

FIG. 7 is a top isometric view of the flexible support with four parallel rows of keys and grooves with light non-transmissive material therein separating respective rows to block light transmission between respective rows;

FIG. 8 is a bottom isometric view of the flexible support showing ribs thereof along with light inlets to the respective rows of the flexible support between adjacent keys and also showing respective activators;

FIG. 9 is a schematic side elevation view of the flexible support with keys thereon and light emitting diodes aligned at respective locations, it being noted that the light emitting diodes are in a different plane relative to the location of the keys, e.g., along the lines of the layout of FIG. 8;

FIG. 10 is a fragmentary enlarged view of a portion of the flexible support, key and light emitting diode;

FIG. 11 is a schematic isometric view of a multi-icon key having light transmissive characteristics with a separator to separate light in one part of the key from illuminating the other side of the key;

FIGS. 12A and 12B are a side elevation section views in two different planes of the key of FIG. 11 mounted on a flexible support and with respect to a printed circuit board, for example, of a portable communication device or other electrical or electronic device;

FIG. 13 is a schematic flow chart illustrating exemplary logic according to which the invention may operate;

FIG. 14 is a schematic illustration representing connections of an operational control of FIG. 2, for example, with respect to four rows of keys of a keypad;

FIG. 15 is a schematic isometric view of another form of arrangement of keys as an integral structure having transparent and opaque portions; and

FIGS. 16 and 17 are schematic elevation views of the integral arrangement of keys of FIG. 15 used to form a key pad, respectively, with a printed circuit board and with a flexible printed circuit board.

### DESCRIPTION

In the detailed description that follows, like components have been given the same reference numerals regardless of whether they are shown in different embodiments of the present invention. To illustrate the present invention in a clear and concise manner, the drawings may not necessarily be to scale and certain features may be shown in somewhat schematic form.

As used herein, the term “portable communication device” includes portable radio communication equipment. Portable communication device and mobile communication device may be used synonymously. The term “portable radio communication equipment,” which may be referred to below as a portable phone (or telephone), a portable device, a portable radio terminal or a portable terminal, includes all electronic equipment, including, but not limited to, mobile telephones, pagers, communicators, e.g., electronic organizers, smartphones, personal digital assistants (PDAs), or the like. While the present invention is being discussed with respect to portable communication devices, it is to be appreciated that the invention is not intended to be limited to portable communication devices, and can be applied to any type of electronic equipment capable of being used for voice and/or data communication.

As will be appreciated, the invention may be used with portable telephones, other telephones, personal digital assistants (PDA), computers, other communication devices, etc.; for brevity, the invention will be described by way of example with respect to portable telephones, but it will be appreciated that the invention may be used with other communication devices.

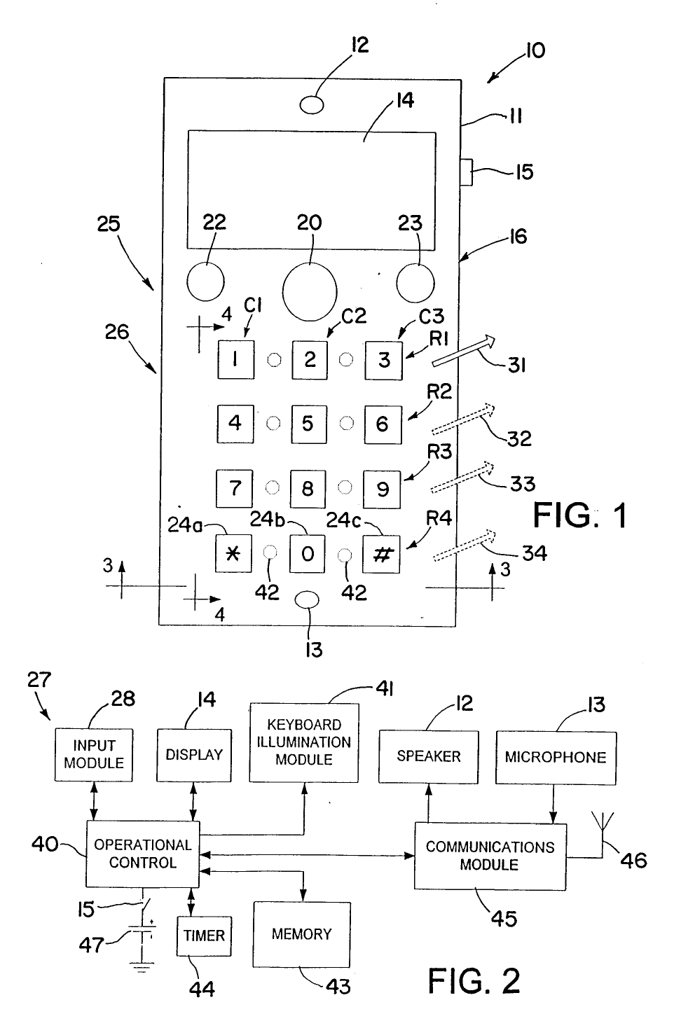

Referring in detail to the drawings, a portable communication device in accordance with an embodiment of the present invention is illustrated generally at 10 in FIG. 1.

The portable communication device will be referred to below as a mobile phone. However, as was mentioned above, reference to “mobile phone” includes various other devices, such as, for example, those mentioned above. In outward appearance, for example, as is illustrated in FIG. 1, the mobile phone is of one type of design or style; however, the features of the invention, as are described in further detail below, may be used in other types of mobile phones, such as those that include cases that open and close, and various other mobile phones that currently exist or may come into existence in the future.

The mobile phone 10 includes case (housing) 11, speaker 12, microphone 13, display 14, e.g., liquid crystal display, light emitting diode display, or other display, on/off switch 15, and a number of keys generally indicated at 16. The keys 16 may include a number of keys having different respective functions. For example, the key 20 may be a navigation key, selection key or some other type of key, and the keys 21, 22 may be, for example, soft keys or soft switches. As an example, the navigation key may be used to scroll through lists shown on the display 14, to select one or more items shown in a list on the display 14, etc. The soft switches 22, 23 may be manually operated to carry out respective functions, such as those shown or listed on the display 14 in proximity to the respective soft switch. The speaker 12, microphone 13, display 14, navigation key 20 and soft keys 22, 23 may be used and function in the usual ways in which a mobile phone typically is used, e.g. to initiate, to receive and/or to answer telephone calls, to send and to receive text messages, to connect with and carry out various functions via a network, such as the Internet or some other network, to beam information between mobile phones, etc. These are examples; there may be other uses, too.

The keys 16 also include a plurality of keys 24 (sometimes referred to as dialing keys, input keys, etc.). In the mobile phone the keys 24 are part of a keyboard 25, and such keys may be operated, e.g., manually or otherwise to provide inputs to circuitry of the mobile phone 10, for example, to dial a telephone number, to create a text message, or to carryout some other function. As is illustrated in FIG. 1, the keys 24 of the keyboard 25 are arranged in the form of a typical mobile phone keypad 26, for example, having four rows R1, R2, R3, R4 of keys with three keys in each row such that there are three columns C1, C2, C3 of keys. In the description below the form of keyboard 25 is described as keypad 26; however, it will be appreciated that features of the invention may be employed in other types of keyboards, e.g., computer keyboards.

The keys 24 are illuminated, and control of such illumination is provided by operating circuitry 27, which is described below with respect to FIG. 2. Such illumination of the keys may be carried out in a number of different ways or patterns, several examples of which are described here. Other ways, patterns or sequences also are possible. In one embodiment the keys 24 in a first row R1 are illuminated to emit light represented by arrow 31, and the other keys 24 are not illuminated. Subsequently the illumination of the keys 24 in row R1 is terminated and the keys 24 in row R2 are illuminated, and the emitting of illumination therefrom is represented by arrow 32. The arrow 32 is shown in dotted outline, as the light it represents occurs subsequently after the light represented by the arrow 31 has ended. Subsequently the operating circuitry 27 may extinguish illumination of the keys 24 in row R2 and illuminate the keys in row R3, the light from which is represented by the arrow 33. Subsequently the operating circuitry extinguishes the illumination of keys in row R3 and illuminates the keys 24 in row R4, the light from which is represented by arrow 34. Such row by row illumination of the keys 24 may be carried out in a repetitive sequence tending to represent something analogous to a flow from top to bottom of the keypad 26 of the mobile phone 10. Alternatively, the sequence may be from bottom to top, e.g., illuminating in sequence rows R4, then R3, then R2, and finally R1. As another alternative, row by row illumination of the keys 24 may be carried out by the operating circuitry 27 in a random sequence, whereby the pattern of rows that are illuminated may be random, e.g., row R2 may be illuminated, followed by row R1, followed by row R4, back to row R2, then to row R3, etc.

In the description below with respect to other drawing figures hereof, the structure of parts of the mobile phone 10 is described that facilitates such row by row illumination of keys 24 while one or more other rows of keys are not illuminated. However, it will be appreciated that the features of the invention may be used to effect column by column illumination of keys 24, e.g., sequential, either random or repetitive, illumination of keys in column C1, column C2, and column C3. In still another embodiment features of the invention may be used to illuminate less than all of the keys in a given row or column while illuminating one or more other keys of that row or column. These are examples of methods for illuminating one or more but not all keys 24; other patterns or sequences are also possible.

Thus, in accordance with an embodiment of the invention, one or more keys 24 are illuminated in a sequence that may be random or repetitive. Such sequential illuminating of keys may provide an interesting visual effect. The sequential illuminating of keys 24 of the keypad 26 also may be used to attract attention; for example, in response to an incoming telephone call or text message or in response to a scheduled event, such as the time an appointment on a calendar, respective keys 24 may be illuminated sequentially to draw attention of the mobile phone user to such telephone call, text message, appointment, etc. Many times the emitting of flashing light draws attention faster and more assuredly than a steady light that is not flashing.

Turning to FIG. 2, a schematic block system diagram of operating circuitry 27 of the mobile phone 10 is illustrated. The illustration is exemplary; other types of circuitry may be employed in addition to or instead of the operating circuitry 27 to carry out the various functions of a mobile phone and the various functions described in detail herein. The operating circuitry includes an operational control 40 that controls the various components of the operating circuitry 27. An input module 28 provides inputs to the operational control, such as, for example, inputs from the various keys 16. Inputs also may be provided from the displayl4 if it is a touch screen type of display, and inputs also may be provided as part of the input module 28 from other connections to the mobile phone, etc. A touch screen, which provides for inputs thereto by touching using a finger, a stylus, or some other device, may provide inputs to the operational control 40. The operational control 40 also may operate the display 14 to determine what information, icons, images, etc. is shown on the display 14.

A keyboard illumination module 41 is coupled to and operates in response to the operational control 40. The keyboard illumination module may include a plurality of light emitting diodes, which are generally indicated at 42 in FIG. 1, for example, two of which are in each row R1 through R4 of the keypad 26. The keyboard illumination module may use other types of light sources, such as, for example, fluorescent lamps, light conducting fibers or the like to which light inputs are provided, etc. In response to inputs from the operational control 40 the keyboard illumination module 41 carries out illuminating of respective keys 24 of the keypad 26, e.g., row by row, column by column, or in some other manner, for example, as was described above.

As an example, the operational control 40 may be a microprocessor or some other electrical or electronic device that is responsive to various inputs, e.g., input signals, and provides various outputs, e.g., output signals. The operational control 40 may be internally programmed or manufactured in a way to include internal programming thereof to carry out various functions. However, in many instances an operational control 40 of a mobile phone 10 would have associated therewith a memory 43 in which appropriate programming instructions, computer program, logic, etc., may be provided the operational control 40 to carry out the functions thereof. The memory 43 also may include storage for telephone numbers and other information concerning contacts who may be called, messaged, etc. using the mobile phone 10, storage of photographs and/or other data, as often is the capability of such memory in conventional mobile phones and may come into existence in the future. The memory 43 may be a read only memory, random access memory, flash RAM, programmable read only memory, or some other memory device. Also associated with the operational control 40 is a timer 44 that can be used to provide timing signals representing increments of time for synchronizing operation of the operating circuitry 27 with some other device, for clock/calendar control functions, and/or for determining amount of time (duration) for illuminating of the keys 24 of the keypad 26, as is described further below.

The operating circuitry 27 also includes a communications module 45 that receives inputs from microphone 13 and provides outputs to the speaker 12, as are common functions in a mobile phone. An antenna 46 may be coupled to the communications module 45 to transmit and to receive signals representing telephone communications, data communications, messages, etc. The communications module may operate under control of the operational control 40 in the usual manner of a mobile phone. Additionally, the communications module 45 may provide an input to the operational control 40 to indicate that there is an incoming telephone call or text message; and in response thereto, the operational control 40 may operate the keyboard illumination module 41 to effect illumination of keys 24 of the keypad 26 in one of the ways described above or in some other way.

A power supply 47 provides electrical power to the operating circuitry 27 via the on/off switch 15. The power supply may be a conventional battery or some other source of electrical power. Upon closing the on/off switch 15, the power is provided the operating circuitry 27 to carry out the various functions described above, for example. If desired, closing the switch 15 may lead to sequential illumination of rows (or columns) of keys 24 of the keypad 26 continuously or for a period of time. For example, upon closing the switch 15, the operational control may cause sequential illuminating of the keys 24 for a period of time determined by the operational control 40 based on time inputs or simply a timing or timer function provided by the timer 40.

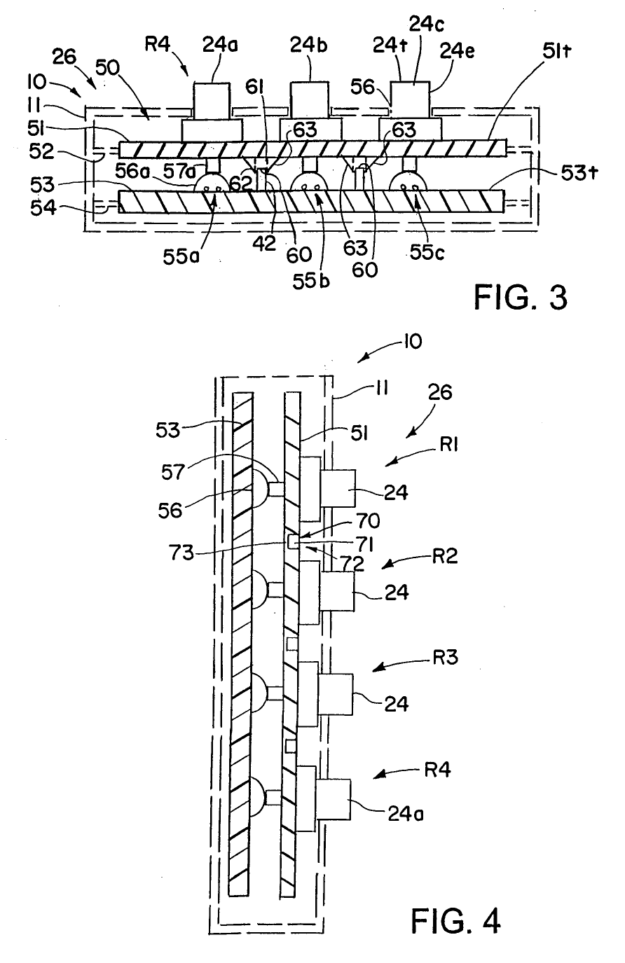

Turning to FIGS. 3-10, the internal structure 50 of the mobile phone 10 to carry out illuminating of respective rows of keys 24 of the keypad 26 without necessarily illuminating the keys in other rows is illustrated. The internal structure 50 also includes a mechanism for providing inputs to the operating circuitry 27, for example, in response to a user manually operating, e.g., pressing, respective keys 24 of the keypad 26. As was mentioned above, the example of keypad 26 and the internal structure 50 is for a mobile phone 10; however, it will be appreciated that the features described may be used with other types of keyboards to effect a desired illuminating of keys thereof while also providing inputs for use by another device, such as, for example, a computer or other electrical or electronic device.

Briefly referring back to FIG. 1, a number of light emitting diodes (LEDs) 42 are illustrated. The LEDs 42 are arranged such that there are two LEDs in each of rows R1, R2, R3 and R4. The two LEDs 42 in row R1 are intended to illuminate only the keys in row R1, and the two LEDs in each of the other three rows are used to illuminate only the keys in those respective rows. A light blocking mechanism, which is described in further detail below, tends to block light that is illuminating keys in one row from illuminating keys in one or more other rows. Again, it is noted that the arrangement of LEDs and light blocking mechanism is described with respect to illuminating separately respective rows of keys of a keyboard; however, a similar arrangement may be used to provide for illuminating separately respective columns or respective keys, or respective groups of keys of the keyboard 25, and such alternate arrangements and functions are within the scope of this invention.

In FIG. 3 is illustrated a schematic bottom end elevation section view looking generally in the direction of the arrows 3-3 of FIG. 1. The internal structure 50 is within the case 11. The part of internal structure 50 shown in FIG. 3 is a representation of keys 24a, 24b, 24c of row R4 of keys 24. The keys 24a-24c are mounted to a flexible support 51, which in turn is mounted in the case 11 by a suitable mounting structure 52. The internal structure 50 also includes a printed circuit board 53, which is suitably mounted in the case 11 by a suitable mounting structure 54. If desired, the flexible support 51 may be mounted to the printed circuit board 53 by a mounting structure (not shown) in addition to or instead of the mounting structure 52. The illustration in FIG. 3 represents internal structure 50 in the area of row R4 of keys 24; however, it will be appreciated that the illustration would be similar with respect to views looking in a cross section through the mobile phone 10 in the direction of the arrows 3-3, respectively, at rows R3, R2 and R1.

The printed circuit board 53 may be a conventional printed circuit board having thereon and/or therein electrical circuitry, electrically conductive paths or traces, integrated circuits, memory circuits, resistors, capacitors, inductors, etc., as may be the case in conventional mobile phones. The printed circuit board 53 may be a single layer or multi-layer printed circuit board. On the top surface 53t (it being noted that directions are for convenience of description but not necessarily limiting) are a number of conductive paths that end at respective terminals schematically illustrated at 55a, 55b, 55c. An electrically conductive dome 56a above the terminals 55a may be resiliently or flexibly deformed to provide an electrically conductive path or connection between the terminals 55a to complete an electrical circuit therebetween and thereby to provide an electrical input, for example, via the input module 28 to the operational control 40 of the operating circuitry 27 (FIG. 2). To effect deforming of the dome 56a, an activator 57a at the bottom surface of the flexible support 51 may be urged against the dome 56a as a user manually presses the key 24a to flex or deform a portion of the flexible support 51 that is proximate or adjacent key 24a. Pressing the key 24a, then, deforms, e.g., stretches, the indicated portion of the flexible support 51 and moves the activator 57a toward the dome 56a. When the user releases manual pressure from the key 24a, the resilient characteristics of the flexible support 51 and/or the dome 56a tend to urge the key 24a away from the printed circuit board, thus moving the key 24a toward the unactivated condition illustrated in FIG. 3 and also allowing the dome 56a to open the electrical connection between the terminals 55a. Similar operation of the keys 24b, 24c with regard to effecting connection between terminals 55b, 55c, respectively, upon pressing such keys, for example, will be appreciated. Associated with such keys 24b, 24c are, respectively, resiliently deformable portions of the flexible support 51, activators 57 and electrically conductive domes 56. The domes may be hemispherical in shape, hollow within, and mounted to the top circuits 53t of the printed circuit board 53 or on a sheet at the surface of the printed circuit board, for example, using tape or some other means. Such mounting of the domes is provided in a manner that avoids unintended electrical connection with circuitry of the printed circuit board 53.

The flexible support 51 is transparent or at least substantially transparent or conductive of light therein. The keys 24 are attached to the top surface 5 it of the flexible support by glue, some other type of adhesive, or by some other means such that light in the flexible support 51 may be conducted to the keys 24. The keys 24 are transparent or substantially conductive of light therein so that light from the flexible support 51 may be transmitted into the respective keys so as to illuminate the keys. Light from the keys may exit, for example, from the top surface or 24t thereof, e.g., the surface at which a user ordinarily would be expected to press a key. Icons on the surface 24t also may be illuminated by light at such surface. Examples of such icons or indicia are illustrated in the mobile phone 10 shown in FIG. 1. The indicia shown in FIG. 1 are numbers, e.g., for dialing a telephone number, plus the asterisk symbol and the pound symbol; additionally, there may be alphabet characters on the keys and/or other indicia and/or icons. The keys 24 have a stepped shape, whereby a portion, e.g., 24e, of relatively narrow cross section in at least one dimension is exposed outside the case 11 via openings 56, and the keys have a flange portion, e.g., 24f, that is of a larger cross section than the cross section of an opening 56 and thereby prevents the key from being pulled out of the case via the opening 56 and/or from being out of glued or adhesive connection to the flexible support 51.

As is seen in FIG. 3, a source of light input to the flexible support 51 is provided by a pair of the LEDs 42 that are located beneath the flexible support 41 between respective pairs of adjacent keys, e.g., keys 24a, 24b and keys 24b, 24c. The LEDs 42 are mounted to the printed circuit board 53 and are attached to circuitry thereof to receive electrical power to provide light output. The light output end 60 of each LED 43 is positioned in a recess 61 of a surface extension, bump or protuberance 62 of the flexible support 51. The extensions 62 may be of the same material of which the flexible support 51 is made and the positioning of light emitting ends 60 of the LEDs 43 in such recesses 61 provides for the directing or conducting of light into the flexible support 51. The flexible support 51 together with extensions 62 thereof provide a light guide to conduct light form the LEDs 43 to illuminate the keys 24a, 24b, 24c. The sizes and shapes of the LEDs 43, recesses 61 and extensions 62 are such that as the flexible support 51 is stretched or flexed toward the printed circuit board 53, as a key is pressed, for example, and after releasing of the key and the flexible support 51 returns to the relaxed state illustrated in FIG. 3, for example, there is adequate space to accommodate the light output end 60 of the LEDs while allowing for movement or travel of the flexible support 51 bearing such flexing thereof without damaging the LEDs and while continuing to maintain a path for light to travel from the LEDs into the flexible support to illuminate the respective keys.

As is seen in FIG. 3, walls 63 of the extensions 62 are slopped so as to provide a truncated conical or pyramid-like shape to the extensions. Light entering the extensions from the respective light emitting diodes will tend to enter directly into the major extent of the flexible support 51, the horizontal extent of which is illustrated in FIG. 3. Also light that does not travel directly from an LED into the major extent of the flexible support, but rather impinges on the inside of the wall 63 may be totally internally reflected at such wall toward the major extent of the flexible support. Similarly, in the major extent of the flexible support light traveling therealong may tend to be totally internally reflected at respective surfaces thereof to provide a light guide effect carrying light to the respective keys 24a, 24b, 24c. Accordingly, the adhesive material with which the keys are attached to the flexible support 51 may be selected, e.g., matching indices of refraction, to minimize total internally reflection at the interface between the keys and the flexible support to achieve a desired amount of light entering the respective keys to eliminate the same.

Further details of the flexible support 51 are described below with respect to FIGS. 4-10. In FIGS. 3 and 4 the flexible support 51 is illustrated schematically without details; those details are illustrated in the subsequent drawing figures. The flexible support may be made of silicone rubber material that has suitable flexibility, resilience, and light conducting characteristics, for example, as are described herein. The flexible support 51 may be another elastomeric or other material. The material of which the flexible support is made should have suitable durability to be capable of being deformed and returning to original shape many times as the respective keys are pressed. In an embodiment illustrated herein the flexible support is a silicone rubber mat; the silicone rubber mat has suitable flexibility, elastomeric characteristics, resilience, etc., as have been described herein.

In FIG. 4 is illustrated a side elevation section view of the mobile phone 10 looking generally in the direction of the arrows 4-4 of FIG. 1. In FIG. 3 the manner of providing light input to the flexible support 51 of a respective row of keys 24, e.g., row R4 is shown, and in FIG. 4 the manner of separating or blocking light from one row of illuminated keys from another row is illustrated. In FIG. 4 the section view is in the plane represented by the arrows 4-4; that which is behind that plane, in particular, the LEDs 42 and extensions 62 providing light input to the flexible support 51 are not seen, as they are in a plane behind where the section of FIG. 4 is taken in FIG. 1; see, for example, the location of the LEDs 42 where the LEDs 42 are behind the keys 24 in the column C1 and, therefore, are not seen in the section 4-4 view of FIG. 4.

As is seen in FIG. 4, the flexible support 51, e.g., the silicone rubber mat, has a number of grooves 70, each of which is between respective parts or portions of the flexible support 51. The grooves 70 extend along the width of the flexible support, the width dimension being in a direction parallel to the respective rows R1-R4 of keys 24. In FIG. 4 the first key 24 in each of the rows R1-R4 is illustrated; and, therefore, the four keys in the first column C1 are seen. The grooves 70 extend along the width of the flexible support 51 crossing through each of the columns C1, C2 and C3.

In the grooves is light non-transparent material 71, e.g., opaque material, that does not transmit light between respective parts or portions of the flexible support 51 on either side of a respective groove 70. The light non-transmissive material may be, for example, non-transparent ink, e.g., black ink or ink of another color, non-transparent paint, e.g., black paint or paint of another color, or some other material. In an embodiment the light non-transmissive material may be molded directly into a respective groove 70, e.g., in a double molding process. As ink or paint, the light non-transmissive material may be painted, flowed, or otherwise applied into the grooves. The grooves 70 with the light non-transmissive material therein form a light block, separator or divider 72 to divide the respective parts or portions of the flexible support 51 that are respectively adjacent a given groove and like non-transmissive material thereby to block transmission of light between those parts or portions of the flexible support. Although the flexible support has a thin portion 73 beneath each groove 70, such portion is sufficiently thin to tend to minimize the amount of light transmitted between respective parts or portions of the flexible support 51 adjacent respective light blocks 72. Moreover, the groove 70 may be shaped so that the interface thereof with the light non-transmissive material that is bounding the thinned portion 73 of the flexible support 51 at the light block 72 may tend to reduce total internal reflection at that interface so that some light in the thinned portions 73 may be absorbed by the light non-transmissive material. For example, light that is traveling in a path toward such interface may not be totally internally reflected but rather may be absorbed.

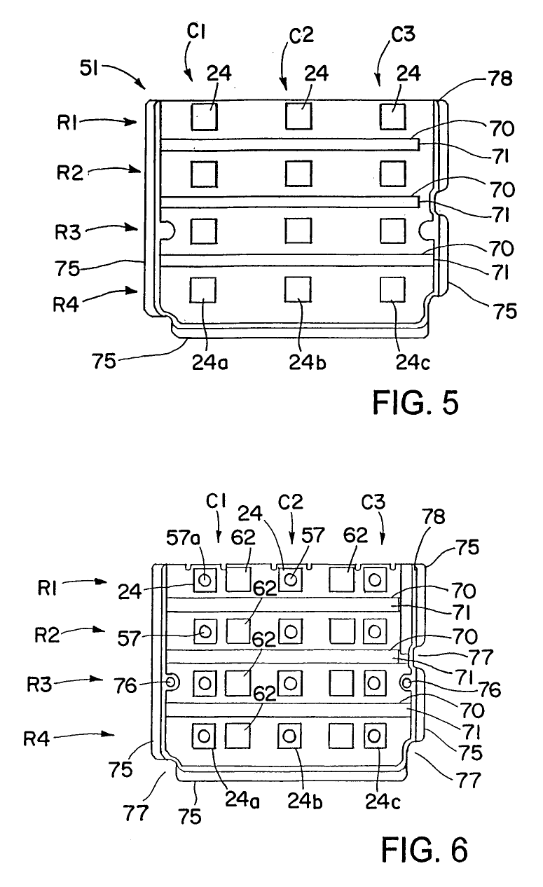

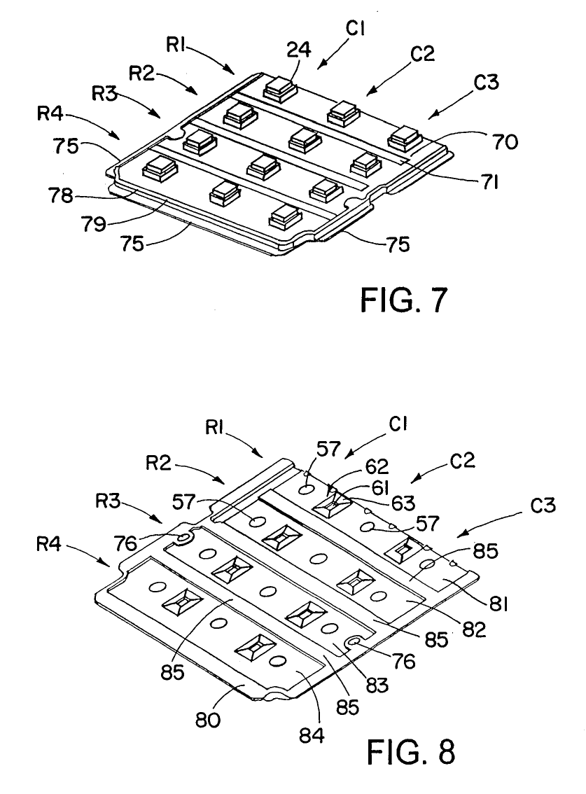

Turning to FIGS. 5-8, the flexible support 51 in the form of a silicone mat is illustrated in greater detail than in FIGS. 3 and 4. FIG. 5 is a top plan view of the flexible support, and FIG. 6 also is a similar top plan view, but provided in a “see-through format.” Therefore, the views of FIGS. 5 and 6 are the same, except that in FIG. 6 the bottom of the flexible support is seen while looking in a direction as though looking through the top plan view of FIG. 5. FIG. 7 is an isometric view of the top of the flexible support; and FIG. 8 is an isometric view of the bottom of the flexible support.

As is seen in FIGS. 5-8, rows and columns of keys 24 are positioned on the flexible support 51. Also, the locations of respective extensions 62 that provide guiding of light input to the flexible support, e.g., from respective LEDs 42 are located between respective pairs of keys in respective rows, e.g., as is seen in FIGS. 6 and 8, for example. The shape of the extensions 62 is shown in FIG. 8; there, the walls 63 of a respective extension 62 provide a truncated pyramid-like shape and have at the center a recess 61 into which the light output end of an LED may be located so as to direct light into the flexible support 51.

A flange 75 extends outward of the flexible support 51 at three edges thereof. The flange may facilitate mounting the flexible support to the case 11 and/or to the printed circuit board 53. Several attachment and/or alignment features, such as, for example, openings 76 and cutouts 77, which are at respective corners and edge of the flexible support facilitate aligning the flexible support with respect to the structure mounting the flexible support in the case 11, e.g., using the mounting structure 52 and/or positioning the flexible support on the printed circuit board 53. The flange 75 may support the flexible support 51 above the printed circuit board with suitable clearance above the domes 56.

Also, surrounding three edges of the flexible support 51 is a relatively raised rim 78, which is seen in FIGS. 5-7. The rim 78 tends to strengthen or stiffen the flexible support to maintain the size and shape thereof as other portions of the flexible support are stretched or flexed as respective keys 24 are pressed. The rim 78 also may facilitate mounting the flexible support 51 in the case 11 of the mobile phone 10.

As is seen in both FIGS. 7 and 8, relative to the top 79 of the rim 78 and the bottom 80 of the flange 75, there is a thinned or relatively recessed part 81, 82, 83, 84 of the flexible support 51. The relatively recessed parts are thinner, i.e., they have a thinner thickness dimension, than the distance between the top 79 of the rim 78 and the bottom 80 of the flange 75. Being thinner, such portions 81-84 of the flexible support 51 tend to be more easily stretched as a key 24 is pressed. Therefore, as a key 24 is pressed, the portion of the flexible support in proximity thereto tends to stretch in a resilient manner so as to allow the activator 57 to press against a conductive dome 56 to complete an electrical connection of terminals 55 on the printed circuit board 53, e.g., as was described above with respect to FIG. 3. Upon releasing the previously pressed key 24 the flexible support 51 has adequate resiliency and elasticity to regain its shape as it was prior to the key being pressed.

As is seen in FIG. 8, beneath each groove 70 is a rib 85. The ribs 85 separate respectively adjacent rows R1-R4 as are represented in FIGS. 7 and 8, for example. The grooves 70 are formed in the flexible support 51 above respective ribs 85. Thus, the ribs 85 provide a strengthening feature for the flexible support 51 holding the various adjacent relatively thin portions 81-84 together, on the one hand, while allowing the grooves 70 to be formed and to contain the light non-transmissive material therein.

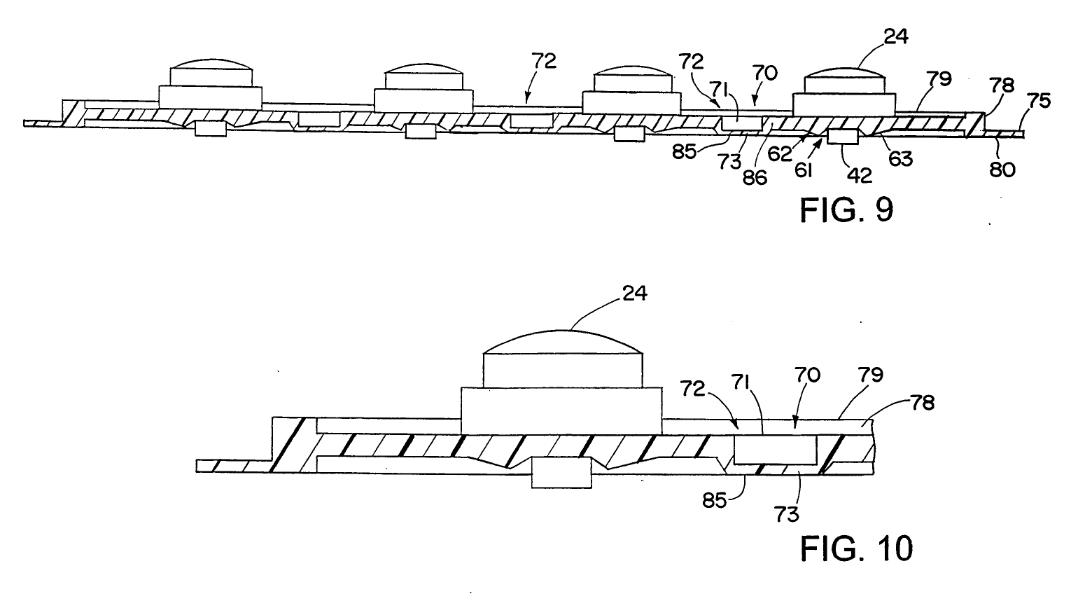

Briefly referring to FIGS. 9 and 10, the actual shape and depth of grooves 70 are seen such that the grooves are below or out of the direct light path of light transmission in a portion 86 of the flexible support that provides light from a LED 42 to a key 24. Therefore, the tendency of light to transmit through the thin material 73 below a groove 70 will be minimal or possibly nonexistent.

With the above description in mind, then, it will be appreciated that the flexible support 51 provides for conducting light to the keys 24 of a given row of a keypad 26 while light is blocked from transmitting between respective rows. Such light blocking is achieved by the light non-transmissive material 71 in respective grooves 70 and also by the locating of the thinned material and ribs 73, 85 below the direct light transmission path from one part or portion of the flexible support in proximity to keys in one row to the part or portion of the flexible support at a relatively adjacent row of keys. The flexible support 51 is an integral structure, as is seen in FIGS. 5-10. Such integral structure helps to provide protection, too, for the printed circuit board 53 and circuitry thereof by blocking foreign substances that may enter the case 11 via openings 56 for the respective keys (FIG. 3).

It will be appreciated that the flexible support 51 together with the keys 24 provide a light guide and keypad 26 as is seen in detail in a number of the drawing figures. The keypad works as a normal numeric keyboard. The row of keys R1, which includes, for example of a telephone keypad, the numbers 1, 2 and 3, and the other rows R2, R3 and R4, which includes numbering of groupings “4 5 6,” “7 8 9,” and “*0#,” may be illuminated or lit up separately. Two LEDs 42 illuminate each row. Light is prevented from leaking between respective rows. Therefore, when the LEDs illuminate one row, only the keys in that row are illuminated. The light is distributed in the silicone rubber mat of which the flexible support 51 is formed. The flexible support may be mounted on the printed circuit board or directly above it in such manner that the ribs 85 and the flange 75 about three sides of the perimeter of the flexible support structure 51 may cooperate with the printed circuit board 53 to block light transmission between adjacent rows from an area beneath the flexible support in the event light were to leak from an LED 42 beneath an extension 62 of the flexible support 51. It is noted that the grooves 70 may be open at the top surface of the flexible support 51, as shown. Alternatively, the grooves may be open at the bottom of the flexible support.

Thus, in such embodiment the grooves in effect are on the backside or bottom of the flexible support 51, and the ribs 85 may be on the top of the flexible support. The arrangement of the ribs, in either event, is as is described above and is illustrated in particular with respect to FIGS. 9 and 10 so that there tends to be little or no light conduction through the respective ribs.

The opaque paint or ink material 71 in the grooves alternatively may be material that is molded into the grooves or is otherwise attached in the grooves. Furthermore, if desired, the opaque parts, e.g., the material in the grooves, may be other than a part of the flexible support 51 and keypad 26, but rather may be another device, e.g., a grid-like device having parts that are inserted into respective grooves or otherwise is positioned with respect to the flexible support to block light transmission between respective rows.

Furthermore, it will be appreciated that the arrangement of grooves, ribs, opaque (light non-transmissive material), etc., may be located between respective columns rather than between respective rows of keys. In such an embodiment respective columns of keys may be illuminated separately without light leaking from one to the other or with minimal light leakage. Still further, if desired, the configurations described above of the flexible support 51, grooves, light blocking material (light non-transmissive material), etc., may be arranged to provide for isolating one key for illumination without illuminating other keys and/or for illuminating several keys that may be in other than a common row or column.

In the exemplary embodiment illustrated and described herein, the silicone rubber material of which the flexible support 51 is made maybe approximately 0.5 millimeter in thickness at the area where keys 24 are attached, e.g., at the respective rows or respective relatively flexible, resilient portions thereof. The thickness of the silicone rubber material where grooves are formed may be on the order of approximately 0.1 millimeter in thickness. Thus, the grooves may be approximately 0.4 millimeter deep. The relatively thin material at the ribs is adequately strong to maintain the integrity of the flexible support as there is parts thereof stretched, flexed, etc. during pressing of a key, for example.

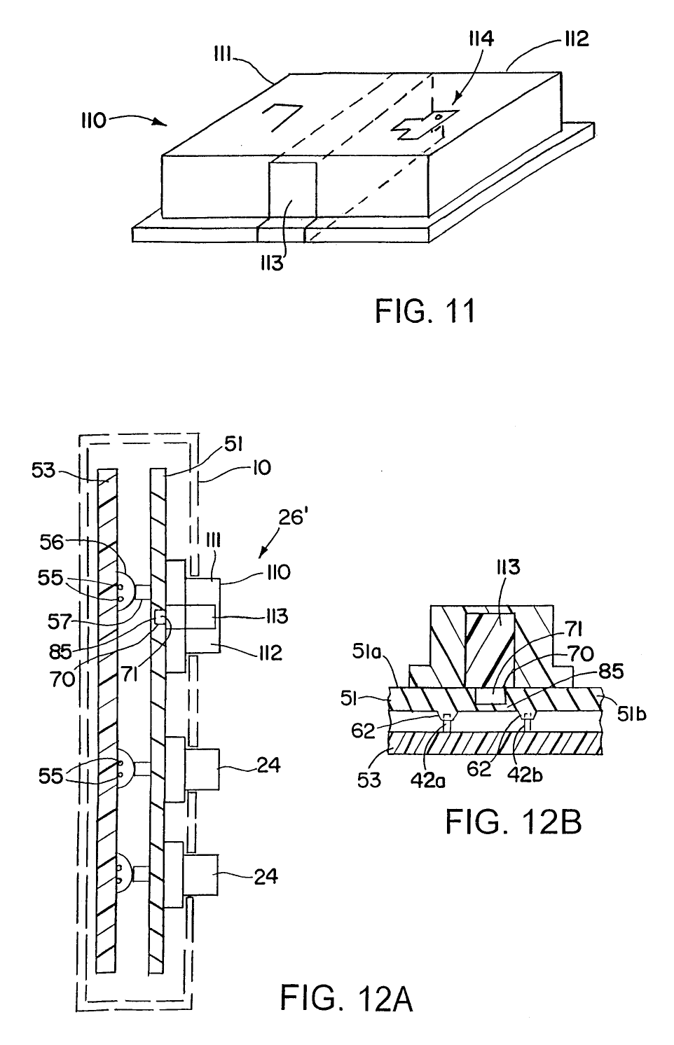

FIGS. 11, 12A and 12B illustrate another embodiment of illuminated keyboard or key pad 26′. In this embodiment the key 110 has two separate sections or parts 111, 112, which are optically separated by a separator or light block 113. Each of the parts of 111, 112 may be illuminated separately and the separator 113 prevents light from one part leaking into the other part. Different respective icons may be provided on the respective key parts 111, 112; as an example, the icon number 7 is shown at the part 111 of the key 110 and a camera icon is shown at 114 on the part 112. The key 110 is mounted on a flexible support 51, for example, using adhesive, as was described above. The separator 113 is located directly above the rib 85 at which a groove 70 having light non-transmissive 71 therein is provided. The separator 113 and the light non-transmissive material 71 in the groove 70 cooperate with each other as a light block to prevent light that illuminates one part 111, 112 from reaching the other of those parts. As is seen in FIG. 12a pressing the key 110 causes stretching of the flexible support 51 so that the activator 57 presses against a dome 56 to complete an electrical connection of terminals 55 on the circuit board 53. The key pad 26′ also includes additional keys 24 that are mounted on the flexible support 51 to be illuminated by light therein and to be pressed to stretch the flexible support to urge an activator 57 against a dome 56 to complete a circuit between respective electrical terminals on a circuit board 53. In the embodiment of keypad 26′ illustrated in FIG. 12a there is no blocking of light in the flexible support from illuminating the part 112 of the key 110 and also the keys 24. Such light blocking may be used, if desired, in a manner illustrated and described above, for example, with respect to FIGS. 3 and 4.

Referring to FIG. 12B, the manner of providing light into the flexible support 51 is illustrated as similar to that described above with respect to FIGS. 3 and 4. As seen in FIG. 12B LEDs 42a, 42b mounted on the printed circuit board 53 provide light input to the flexible support 51 at respective extensions 62. The separator 113, light non-transmissive material 71 in the groove 70, and the arrangement of the rib 85 between respective parts of the flexible support 51 block light transmission between those respective parts of the flexible support, for example, parts 51a and 51b. The LED 42a may be of a different color than the LED 42b. Therefore, when the LED 42a is illuminated, the part 111 of the key 110 is illuminated in one color, whereas when the LED 42b is energized, the part 112 of the key 110 is illuminated by a different color light. Operation of the keypad 26′ otherwise may be the same as operation of the keypad 26 described above with respect to FIGS. 1-10, for example, except the key 110 can be illuminated at different parts using different color light. Both parts may be illuminated if both LEDs 42a, 42b are energized; or only one part may be illuminated if only one of those LEDs is energized.

The key 110 may be made, for example, of a clear plastic material, such as, for example, polycarbonate. Such material is light transmissive. The separator 113 may be made of polycarbonate acrylonitrile butadiene styrene (PC/ABS). The PC/ABS material is light non-transmissive (optically non-transmissive, opaque, etc.) and is compatible with the polycarbonate material of which the balance of the key 110 is made. The separator 113 is located in proximity to the light non-transmissive material 71 in the groove 70 to obtain light blocking effect described above.

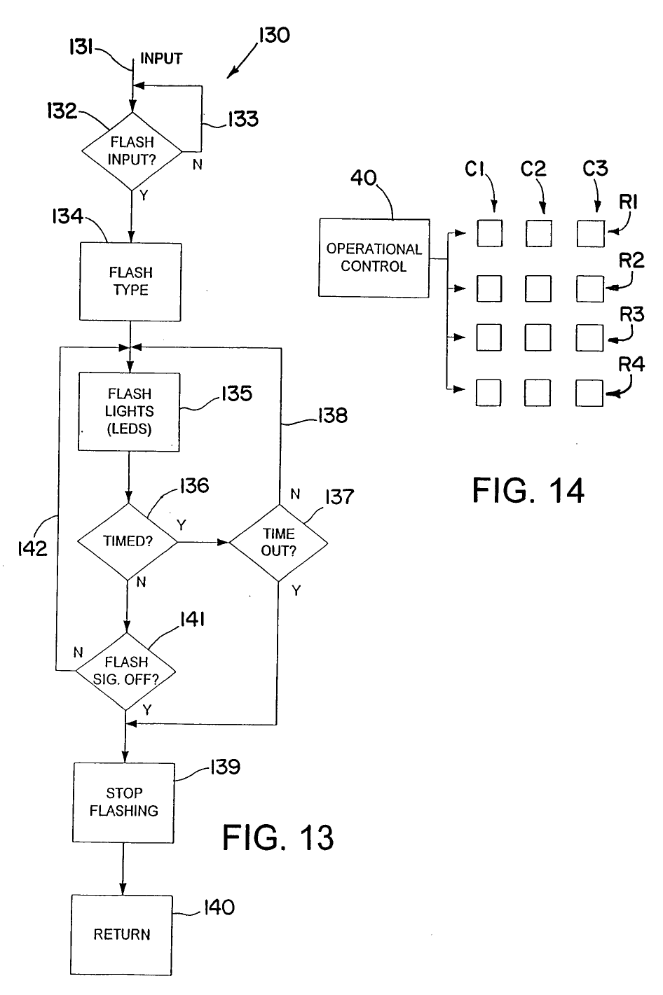

A computer program flow chart or logic diagram is illustrated at 130 in FIG. 13. Such flow chart 130 represents functions that may be carried out in the operating circuitry 27 in carrying out an embodiment of the invention as an example. The functions illustrated in FIG. 13 and described herein may be provided the operating circuitry 27 as a computer program, for example, that is written in appropriate computer language or logic format to carry out the various steps described. A person having ordinary skill in the art would be able to write such program to carry out the steps and functions illustrated and described here.

Initially an input is provided at 131. The input may be, for example, detecting by the operational control 40 that a telephone call is being received. If an input is received at 131, then at step 132 an inquiry is made to determine whether the input is a “flash input” meaning that it is desired to flash, pulse or otherwise illuminate the keyboard 25 of the mobile phone 10 in a sequential manner, such as was described above. If the input is one that does not require a flashing of the keyboard or illuminating of the keyboard, then loop 133 is followed until such an input is received. If the input is a flash input, then at step 134 an inquiry is made as what type of flash input is appropriate based on such input. For example, one type of flash input, e.g., one type of sequence may be used if the input represents an incoming telephone call, and a different sequence may be used if the input represents that a text message has been received.

After determining the flash type, then at step 135 the LEDs 42 are flashed in an appropriate sequence according to the flash type. The flashing may be timed, e.g., based on the timer 44. For example, it may be desired to flash the LEDs only for, say, one minute or less, or it may be desired to flash the LEDs for a longer period of time. The time may be determined by the timer 44. If the flashing is to be timed at step 136, then at step 137 an inquiry is made whether the time has expired. If it has not, then loop 138 is followed until the time has expired. If the timer 44, for example, has timed out, then from step 137 the flow chart follows to step 139, whereupon flashing is terminated, and the routine 130 illustrated in FIG. 13 returns to a wait or inactive state as is represented at step 140.

It may be that the flashing of lights may not be intended to be timed, and, therefore, at step 136 the logic flows to step 141. An example of untimed flashing may be when the user specifically turns on the flashing and does not intend the flashing to stop until manually turned off. This may be carried out by appropriate operation of the navigation key 20 and/or one or more soft switches 20, 22. Accordingly, at step 141 if the flashing signal has not been turned off by the user, then loop 142 is followed until the flash signal has been turned off. When the flash signal has been turned off, then at step 139 flashing is stopped, and the system returns to a wait state, for example at step 140.

FIG. 14 schematically illustrates the relationship of the operational control 40 (FIG. 2) with the illuminating of the twelve keys in respective rows R1-R4 and/or columns C1-C4. The operational control 40 may respond to the particular type of flash input or flash signal received at the flash input 132 and determined by the flash type 134. Based on that signal, the operational control 40 may flash the LEDs sequentially in a repetitive or random fashion, depending on the flash input and flash type. If the keypad 26 is set to flash respective columns rather than respective rows, then the operational control 40 may flash respective columns C1-C3 of keys 24.

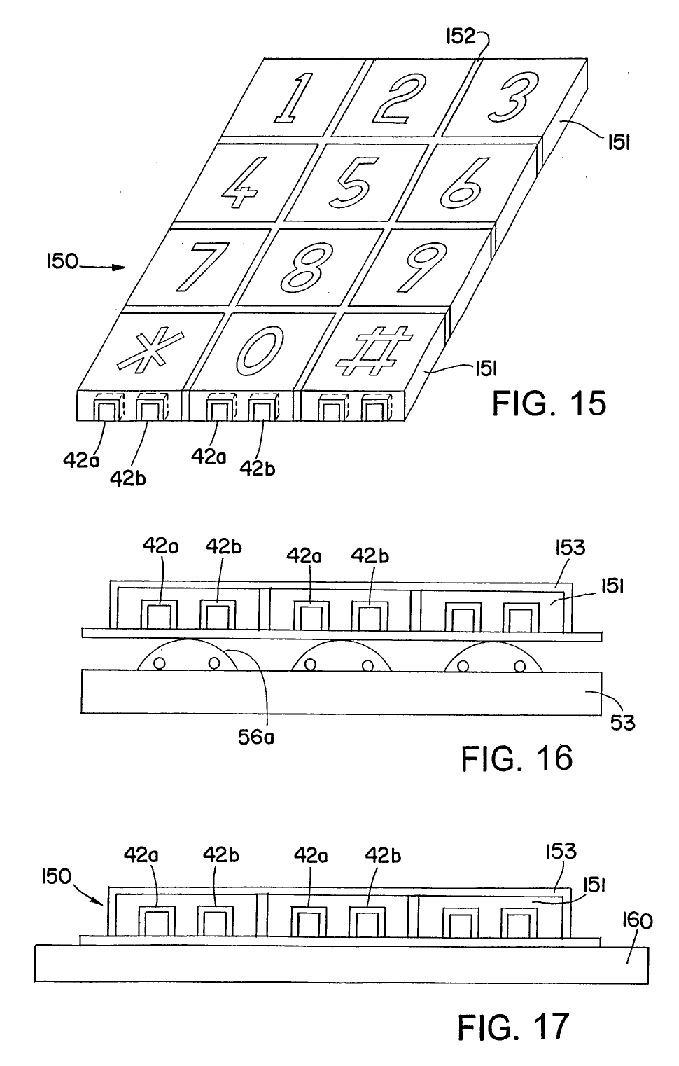

Referring to FIGS. 15-17, another embodiment that the invention is illustrated. In FIG. 15 is shown a double molded part 150, that may serve as a touch pad. The double molded part 150 includes a number of transparent sections 151 between which a grid 152 of opaque material is provided. The transparent portions 151 may be made of plastic, for example, or of silicone rubber, such as that which was described above with regard to the flexible support 51. The opaque portion 152 may be a material known as TPU, which is an elastic polymer. Such TPU material is sold by BASF, which is a manufacturer of thermoplastic polyurethane elastomers (TPU). One form of such material is sold under the trademark “ELASTOLLAN” by BASF of Wyandotte, Mich. The part 150 being made of resilient, flexible material may be used in the manner described above as a keypad for the mobile phone 10 or for some other device. In such an embodiment, which is illustrated in FIG. 16, the flexible, resilient part 150 is shown in position relative to a printed circuit board 53 so as to be able press against respective domes 56a, for example, to complete circuits on the printed circuit board. The device 150 may be suitably flexible such that by pressing at one section 151a dome 56a is deformed without deforming other domes. The sections 151 may include one or more light emitting diodes 42a, 42b, for example, of different respective colors. The diodes may be electrically connected to circuits on the printed circuit board 53 to receive electrical power and in response thereto to provide the light output. The light output illuminates the respective section 151. As is seen in FIG. 15, there are twelve sections 151, each of which is optically separated from the others by the opaque material 152 in the form of a grid between the respective sections 151. Therefore, light in one section 151 will not illuminate other sections.

As is seen in FIG. 16, the part 150 is coated, e.g., by painting, spraying, metalizing, or some other process, with a light non-transmissive coating 153. The coating 153 may be light reflecting so as to reflect light within a given section 151. At the top surface of the material 153 an icon may be formed, e.g., by laser inscribing thereon. An example of such laser inscribing is shown in FIG. 15, where the numbers 1 through 0 and the * and # signs are inscribed at the respective sections 151. Light provided by the respective LEDs may illuminate the respective icons. The LEDs may be different colors, and, therefore, the illuminated effect of the respective icons may change, depending on the color.

FIG. 17 illustrates another embodiment using the part 150, wherein the part 150 is mounted on a flexible printed circuit board 160. The flexible printed circuit board may have circuits thereon and also may have various pressure sensitive switches thereon or therein. The part 150 in such instance may be either flexible, as was described above, or may be a relatively hard immaterial such as, for example, polycarbonate of which the transparent sections 151 may be formed and polycarbonate acrylonitrile butadiene styrene (PC/ABS) of which the opaque grid at 152 may be formed. Such materials are compatible and may be molded together in a double molding process. Pressing on a respective section 151 of the part 150 may compress a part of the flexible printed circuit board 160 to close a switch and to provide an appropriate response.

It will be appreciated that portions of the present invention can be implemented in hardware, software, firmware, or a combination thereof. In the described embodiment(s), a number of the steps or methods may be implemented in software or firmware that is stored in a memory and that is executed by a suitable instruction execution system. If implemented in hardware, for example, as in an alternative embodiment, implementation may be with any or a combination of the following technologies, which are all well known in the art: discrete logic circuit(s) having logic gates for implementing logic functions upon data signals, application specific integrated circuit(s) (ASIC) having appropriate combinational logic gates, programmable gate array(s) (PGA), field programmable gate array(s) (FPGA), etc.

Any process or method descriptions or blocks in flow charts may be understood as representing modules, segments, or portions of code which include one or more executable instructions for implementing specific logical functions or steps in the process, and alternate implementations are included within the scope of the preferred embodiment of the present invention in which functions may be executed out of order from that shown or discussed, including substantially concurrently or in reverse order, depending on the functionality involved, as would be understood by those reasonably skilled in the art of the present invention.

The logic and/or steps represented in the flow diagrams of the drawings, which, for example, may be considered an ordered listing of executable instructions for implementing logical functions, can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer readable medium can be, for example, but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via, for instance, optical scanning of the paper or other medium, then compiled, interpreted or otherwise processed in a suitable manner if necessary, and then stored in a computer memory.

The above description and accompanying drawings depict the various features of the invention. It will be appreciated that the appropriate computer code could be prepared by a person who has ordinary skill in the art to carry out the various steps and procedures described above and illustrated in the drawings. It also will be appreciated that the various terminals, computers, servers, networks and the like described above may be virtually any type and that the computer code may be prepared to carry out the invention using such apparatus in accordance with the disclosure hereof.

Specific embodiments of an invention are disclosed herein. One of ordinary skill in the art will readily recognize that the invention may have other applications in other environments. In fact, many embodiments and implementations are possible. The following claims are in no way intended to limit the scope of the present invention to the specific embodiments described above. In addition, any recitation of “means for” is intended to evoke a means-plus-function reading of an element and a claim, whereas, any elements that do not specifically use the recitation “means for”, are not intended to be read as means-plus-function elements, even if the claim otherwise includes the word “means”.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

We claim:

1. A keyboard, comprising
a plurality of keys,
a flexible support adapted to support a plurality of keys,
at least part of the flexible support being at least partly transmissive of light to conduct light to illuminate a plurality of keys, and
a light block adapted to tend to block light transmission between a pair of relatively adjacent parts of the flexible support.

2. The keyboard of claim 1, said flexible support comprising a silicon mat.

3. The keyboard of claim 1, the light block comprising a groove in said flexible support between respective parts thereof, and light blocking material in the groove.

4. The keyboard of claim 3, said light blocking material comprising material molded directly in the groove.

5. The keyboard of claim 1, further comprising a plurality of light sources, and recesses in a surface of said flexible material, said recesses adapted to conduct light from respective light sources directly to respective at least partly light transmissive parts of said flexible support.

6. The keyboard of claim 1, further comprising a reflective coating on at least part of the flexible support to avoid light leakage and to provide a light guide effect.

7. The keyboard of claim 1, said keys being attached to the flexible support.

8. The keyboard of claim 1, further comprising a respective icon on a plurality of the keys.

9. The keyboard of claim 1, wherein the keys are arranged in a plurality of rows with one or more keys in each row, a plurality of light sources arranged with respect to the flexible support and the light block thereof such that the keys of different rows are illuminated by a different respective a light source.

10. The keyboard of claim 9, further comprising a control adapted to control operation of the respective light sources to illuminate less than all rows of keys at a time.

11. The keyboard of claim 10, said control being adapted to control operation of the respective light sources to illuminate each of the rows of keys in a repeating sequence or random sequence.

12. The keyboard of claim 1, at least a plurality of said keys being selectively operable to effect an input to a portable communication device.

13. The keyboard of claim 1, further comprising a housing, a circuit board of portable electronic equipment including a support and circuitry in the housing, the flexible support mounted in the housing with respect to the housing or the circuit board, a plurality of said keys being manually selectively operable to effect providing an input to said circuitry, and a source of input light adapted to provide light to respective parts of the flexible support to illuminate one or more respective keys.

14. The keyboard of claim 1, further comprising a source of illumination adapted to illuminate a plurality of the keys, and a control adapted to control operation of the source of illumination to provide for random or sequential illuminating of respective keys or groups of keys.

15. The keyboard of claim 14, said control being adapted to detect a prescribed input and in response to such prescribed input controlling operation of the source of illumination in a prescribed manner.

16. The keyboard of claim 15, said control being adapted to detect an incoming telephone call as such prescribed input.

17. A portable electronic equipment, comprising
a keyboard having a number of keys adapted to provide inputs to the portable electronic equipment,
a keyboard illumination system, including
a flexible support adapted to support keys of the keyboard,
the flexible support being at least partly light transmissive to conduct light to illuminate a plurality of keys, and
a light block in the flexible support adapted to block transmission of light in the flexible support from illuminating at least one other key.

18. The equipment of claim 17, wherein the flexible support comprises a number of relatively thick rib portions providing stiffness for the flexible support, and relatively thin flexible portions between respective ribs.

19. The equipment of claim 18, further comprising raised surfaces on said relatively thin flexible portions with an open clearance circumscribed by said raised surfaces providing space for at least a portion of a light source to align with said open clearance to provide light input for transmission in the flexible support, and further comprising light emitting diodes aligned with respective open clearances adapted to provide light into the flexible support.

20. The equipment of claim 18, wherein the flexible support includes locations at one surface for a number of keys positionable in respective parallel rows and/or respective parallel columns, the light block comprises a light block between respective parallel rows or parallel columns, and inputs to the flexible support such that light input to the flexible support at a light input in one row or column is provided to illuminate adjacent keys in such one row or column.

21. The equipment of claim 20, wherein the keys are in respective rows and a number of the rows include locations for at least three keys, the light input for a row comprises at least two light inputs, each located between a pair of locations for keys of that row, and the light block blocks at least a substantial amount of light transmission between respective rows.

22. The equipment of claim 20, further comprising operating circuitry adapted to operate and to carry out functions of the portable electronic equipment.

23. The equipment of claim 22, comprising a portable communication device, and wherein the operating circuitry comprises a communication module to send and receive at least one of voice or text, and further comprising a housing for the keyboard, keyboard illumination system and operating circuitry.

24. A method of illuminating keys of a keyboard having a plurality of keys arranged in at least one of a plurality of rows or a plurality of columns, comprising,
selectively illuminating sequentially one or more, but less than all, of the keys of the keyboard in a random or a repetitive sequence.

25. The method of claim 24, said selectively illuminating comprising illuminating at least a row of keys or a column of keys without illuminating another row of keys or column of keys.

26. A key for a keyboard, comprising,
a key body,
the key body having an at least partly light transmissive portion,
a separator in the key body adapted to block light transmission between at least two parts of the key body, and
at least two light inlets, one adapted to provide light to one part of the key body and one to provide light to another part of the key body.

27. A touch pad keyboard comprising a molded part that is integral including light transmissive or transparent sections and a grid of opaque sections between such transparent sections.
